(19) United States
(12) Patent Application Publication
(10) Pub. No.: US 2013/0133715 A1
(43) Pub. Date: May 30, 2013

(54) SOLAR CELL, AND SOLAR CELL SYSTEM

(71) Applicants: YUAN-HAO JIN, Beijing (CN); QUN-QING LI, Beijing (CN); SHOU-SHAN FAN, Beijing (CN)

(72) Inventors: YUAN-HAO JIN, Beijing (CN); QUN-QING LI, Beijing (CN); SHOU-SHAN FAN, Beijing (CN)

(73) Assignees: HON HAI PRECISION INDUSTRY CO., LTD., Tu-Cheng (TW); TSINGHUA UNIVERSITY, Beijing (CN)

(21) Appl. No.: 13/474,940

(22) Filed: May 18, 2012

(30) Foreign Application Priority Data
Nov. 25, 2011 (CN) 201110380590.1

(51) Int. Cl. H01L 31/05; H01L 31/0232; H01L 31/0264

(52) U.S. Cl. 136/244; 136/261; 136/259

(57) ABSTRACT

A solar cell includes a first electrode layer, a P-type silicon layer, an N-type silicon layer, a second electrode layer, and a reflector. The first electrode layer, the P-type silicon layer, the N-type silicon layer, and the second electrode layer are arranged in series side by side along a first direction and in contact with each other, thereby cooperatively forming a integrated structure. A P-N junction is formed near an interface between the P-type silicon layer and the N-type silicon layer. The integrated structure has a first surface substantially parallel to the first direction and a second surface opposite to the first surface. The first surface is used as a photoreceptive surface to directly receive incident light. The reflector is located on the second surface of the integrated structure.

### CROSS-REFERENCE TO RELATED APPLICATIONS

This application claims all benefits accruing under 35 U.S.C. §119 from China Patent Application No. 201110380590.1, filed on Nov. 25, 2011, in the China Intellectual Property Office, the contents of which are hereby incorporated by reference.

### BACKGROUND

1. Technical Field

The present disclosure relates to a solar cell, and a solar cell system.

2. Description of Related Art

An operating principle of a solar cell is photoelectric effect of a semiconducting material. The solar cells can be roughly classified into silicon-based solar cells, gallium arsenide solar cells, and organic thin film solar cells.

A silicon-based solar cell commonly includes a rear electrode, a P-type silicon layer, an N-type silicon layer, and a front electrode. The P-type silicon layer can be made of polycrystalline silicon or monocrystalline silicon and has a first surface and a flat second surface opposite to the first surface. The rear electrode is disposed on and in ohmic contact with the first surface of the P-type silicon layer. The N-type silicon layer is formed on the second surface of the P-type silicon layer and serves as a photoelectric conversion element. The N-type silicon layer has a flat surface. The front electrode is disposed on the flat surface of the N-type silicon layer. The P-type silicon layer and the N-type silicon layer cooperatively form a P-N junction near an interface of the P-type silicon layer and the N-type silicon layer. In use, light directly irradiates the front electrode, and reaches the P-N junction through the front electrode and the N-type silicon layer. Consequently, a plurality of electron-hole pairs (carriers) can be generated in the P-N junction due to photon excitation. Electrons and holes in the electron-hole pairs can be separated from each other and separately move toward the rear electrode and the front electrode under an electrostatic potential. If a load is connected between the front electrode and the rear electrode, a current can flow through the load.

However, a light absorbing efficiency of the P-N junction of the above solar cell is low, because partial photons in the incident light are absorbed by the front electrode and the N-type silicon layer. Thus, carriers generated by exciting of photons in the P-N junction are relatively few, and a photoelectric conversion efficiency of the solar cell is relatively low.

What is needed, therefore, is to provide a solar cell having high photoelectric conversion efficiency, a solar cell system, and a method for making the same.

### BRIEF DESCRIPTION OF THE DRAWING

Many aspects of the present disclosure can be better understood with reference to the following drawings. The components in the drawings are not necessarily to scale, the emphasis instead being placed upon clearly illustrating the principles of the present embodiments.

FIG. 1 is a front view of a first embodiment of a solar cell.

FIG. 2 is a structural schematic view of the solar cell of FIG. 1.

FIG. 3 is a front view of an embodiment of a solar cell system using the solar cell of FIG. 1.

FIG. 4 is a front view of a second embodiment of a solar cell.

FIG. 5 is a front view of an embodiment of a solar cell system using the solar cell of FIG. 4.

FIG. 6 is a front view of a third embodiment of a solar cell.

FIG. 7 is a front view of an embodiment of a solar cell system using the solar cell of FIG. 6.

FIG. 8 is a flow chart of an embodiment of a method for making a solar cell system.

### DETAILED DESCRIPTION

The disclosure is illustrated by way of example and not by way of limitation in the figures of the accompanying drawings in which like references indicate similar elements. It should be noted that references to “another,” “an,” or “one” embodiment in this disclosure are not necessarily to the same embodiment, and such references mean at least one.

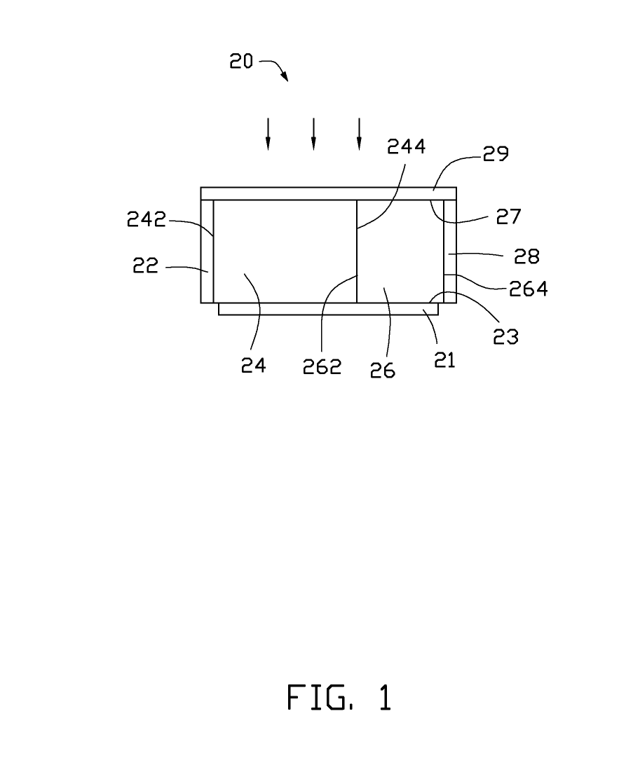

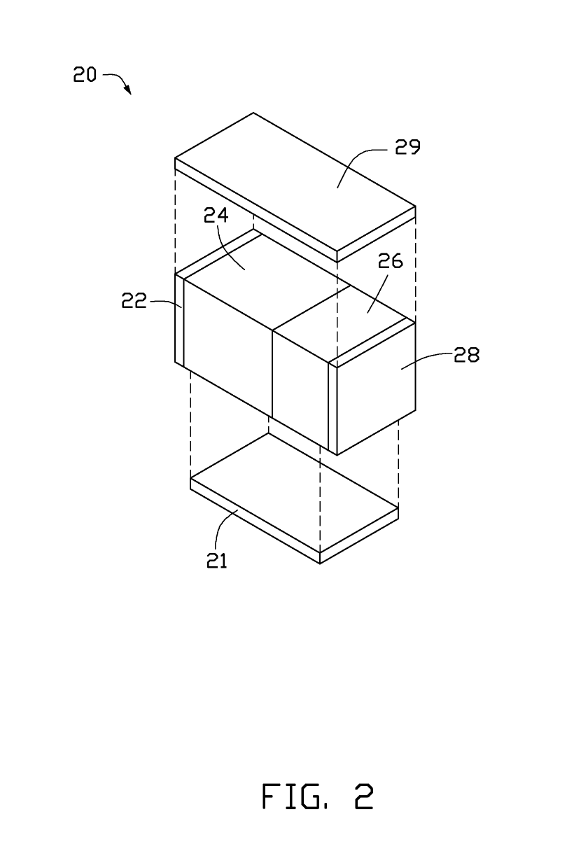

Referring to FIGS. 1 and 2, a first embodiment of a solar cell 20 includes a first electrode layer 22, a P-type silicon layer 24, an N-type silicon layer 26, a second electrode layer 28, and a reflector 21.

The first electrode layer 22, the P-type silicon layer 24, the N-type silicon layer 26, and the second electrode layer 28 can be arranged in series along a first direction, side by side, in that order, cooperatively forming an integrated structure. The integrated structure includes a first surface 27 and a second surface 23 opposite to the first surface 27. The first surface 27 is parallel with the first direction and used as a photoreceptive surface to receive an incident light. In particular, the P-type silicon layer 24 has a first side surface 242 and a second side surface 244 opposite to the first side surface 242. The N-type silicon layer 26 has a third side surface 262 and a fourth side surface 264 opposite to the third side surface 262. The first electrode layer 22 is electrically connected with and contacting the first side surface 242 of the P-type silicon layer 24. The second electrode layer 28 is electrically connected with and contacting the fourth side surface 264 of the N-type silicon layer 26. The second side surface 244 of the P-type silicon layer 24 and the third side surface 262 of the N-type silicon layer 26 are electrically connected with and contacting each other to form a P-N junction. The P-N junction is exposed out from the first surface 27. The reflector 21 is located on the second surface 23 and insulated from the first electrode layer 22 and the second electrode layer 28.

The P-type silicon layer 24 has a first top surface (not labeled) and a first bottom surface (not labeled) connected with the first side surface 242 and the second side surface 244. The N-type silicon layer 26 has a second top surface (not labeled) and a second bottom surface (not labeled) connected with the third side surface 262 and the fourth side surface 264. The first top surface of the P-type silicon layer 24 and the second top surface of the N-type silicon layer 26 are coplanar. The first bottom surface of the P-type silicon layer 24 and the second bottom surface of the N-type silicon layer 26 are coplanar. The P-N junction is formed near an interface between the P-type silicon layer 24 and the N-type silicon layer 26.

The P-type silicon layer 24 is a laminar structure. A material of the P-type silicon layer 24 can be monocrystalline silicon, polycrystalline silicon, or other P-type semiconducting material. A thickness of the P-type silicon layer 24 along the first direction from the first side surface 242 to the second side surface 244 can be in a range from about 200 micrometers (μm) to about 300 μm. An angle between the first top surface and the first side surface 242 or the second side surface 244 can be larger than 0 degrees and less than 180 degrees. In one embodiment, the angle is about 90 degrees, namely, the first top surface is substantially perpendicular to the first side surface 242 and the second side surface 244, and the P-type silicon layer 24 is a P-type monocrystalline silicon sheet having 200 μm in thickness.

The N-type silicon layer 26 is also a laminar structure. The N-type silicon layer 26 can be formed by injecting superfluous N-type doping elements (e.g. phosphorus or arsenic) into a silicon sheet. A thickness of the N-type silicon layer 26, along the first direction from the third side surface 262 to the fourth side surface 264, can be in a range from about 10 nanometers (nm) to about 1 μm. An angle between the second top surface and third side surface 262 and the fourth side surface 264 can be larger than 0 degrees and less than 180 degrees. In one embodiment, the angle is about 90 degrees, namely, the first side surface is perpendicular to the third side surface 262 and the fourth side surface 264, and the thickness of the N-type silicon layer 26 is about 50 nm.

An inner electric field having a field direction from the N-type silicon layer 26 to P-type silicon layer 24 is formed, because surplus electrons in the N-type silicon layer 26 diffuse across the P-N junction and reach the P-type silicon layer 24. When a plurality of electron-hole pairs are generated in the P-N junction due to excitation of an incident light, the electrons and the holes are separated from each other under the inner electric field. Specifically, the electrons in the N-type silicon layer 26 move toward the second electrode layer 28, and are gathered by the second electrode layer 28. The holes in the P-type silicon layer 24 move toward the first electrode layer 22, and are gathered by the first electrode layer 22. Thus, a current is formed, thereby realizing a conversion from the light energy to the electrical energy.

In use, the incident light does not reach the P-N junction through the first electrode layer 22, namely, the first electrode layer 22 will not obstruct the incident light to reach the P-N junction. Thus, the first electrode layer 22 can be a continuous planar shaped structure coated on the entire first side surface 242 of the P-type silicon layer 24, or a lattice shaped structure coated on the partial surface 242 of the P-type silicon layer 24. A material of the first electrode layer 22 is conductive material, such as metal, conducting polymer, indium tin oxide, and carbon nanotube structure. In one embodiment, the first electrode layer 22 is made of a metal layer having a continuous planar shaped structure and coated on the entire first side surface 242. The metal can be aluminum, copper, or silver. A thickness of the first electrode layer 22 is not limited, and can be in a range from about 50 nm to about 300 nm. In one embodiment, the first electrode layer 22 is an aluminum sheet having a thickness of 200 nm.

Furthermore, the incident light does not reach the P-N junction through the second electrode layer 28. Thus, the second electrode layer 28 can be a continuous planar shaped structure coated on the entire fourth side surface 264 of the N-type silicon layer 26, or a lattice shaped structure partially coated on the fourth side surface 264. A material of the second electrode layer 28 can be conductive material, such as metal, conducting polymer, indium tin oxide, and carbon nanotube structure. In one embodiment, the second electrode layer 28 is made of a metal layer having a continuous planar shaped structure and coated on the entire fourth side surface 264. The metal can be aluminum, copper, or silver. A thickness of the second electrode layer 28 is not limited, and can be in a range from about 50 nm to about 300 nm. In one embodiment, the second electrode layer 28 is an aluminum sheet having a thickness of 200 nm.

In addition, the material of the first electrode layer 22 and the second electrode layer 28 can be opaque to avoid leakage of the incident light passing through the first electrode layer 22 and the second electrode layer 28, thus the photoelectric conversion efficiency of the solar cell 20 is improved.

The reflector 21 can be a continuous reflection layer directly in contact with the second surface 23 and spaced from the first electrode layer 22 and the second electrode layer 28. The reflector 21 can be made of metal such as aluminum, gold, copper or silver. The thickness of the reflector 21 can be in a range from about 10 nm to about 100 μm. In one embodiment, the reflector 21 is aluminum foil with a thickness of about 50 nm. The reflector 21 can be formed on the second surface 23 by vacuum evaporation or magnetron sputtering.

The incident light irradiates the first surface 27 of solar cell 20. The second electrode layer 28 does not coat the first surface 27, namely, the P-N junction is directly exposed from the first surface 27. Thus, the photons in the incident light directly reach the P-N junction without passing through the second electrode layer 28 and the first electrode layer 22, and can be directly absorbed by the P-N junction. Accordingly, the second electrode layer 28 and the first electrode layer 22 cannot obstruct the incident light to reach the P-N junction, thereby increasing the light absorbing efficiency of the P-N junction. Correspondingly, the P-N junction can excite more electron-hole pairs under the irradiation of the incident light. In addition, the second electrode layer 28 can have any shape and cannot obstruct light. In one embodiment, the second electrode layer 28 having a planar shaped structure is coated on the entire fourth side surface 264 of the N-type silicon layer 26. Thus, the second electrode layer 28 has a large area, thereby decreasing the diffusing distance of the carriers in the second electrode layer 28 and the interior loss of the carriers, and increasing the photoelectric conversion efficiency of the solar cell 20.

In addition, an angle between the first surface 27 and the fourth side surface 264 of the N-type silicon layer 26 can be in a range from about 0 degrees to about 180 degrees. In one embodiment, the angle is about 90 degrees.

Furthermore, an antireflection layer 29 can be disposed on the first surface 27 to decrease reflection of the incident light and increase absorption of the incident light. The antireflection layer 29 can absorb little light. A material of the antireflection layer 29 can be silicon nitride (Si₃N₄) or silicon dioxide (SiO₂). A thickness of the antireflection layer 29 can be less than 150 nm. In one embodiment, the antireflection layer 29 is the silicon nitride layer having the thickness of 900 angstrom (Å).

A thickness of the solar cell 20 is a distance between the first surface 27 and a second surface 23. When the first surface 27 is substantially perpendicular to the fourth side surface 264, the thickness of the solar cell 20 is a width of the P-type silicon layer 24, N-type silicon layer 26, a first electrode layer 22, or a second electrode layer 28 along a direction perpendicular to the first surface 27. The thickness of the solar cell 20 is not limited, and can be set by the light transmittance of the P-type silicon layer 24 and the N-type silicon layer 26. Specifically, if the light transmittance of the P-type silicon layer 24 and the N-type silicon layer 26 is large, the thickness of the solar cell 20 can be appropriately increased to decrease the light transmittance. Consequently, the solar cell 20 can efficiently absorb the light. In one embodiment, the thickness of the solar cell 20 is in a range from about 50 μm to about 300 μm.

The first electrode layer 22 and the second electrode layer 28 will not obstruct the light to irradiate the P-N junction. Thus, the shape and structure of the first electrode layer 22 and the second electrode layer 28 can be arbitrarily set, thereby decreasing the complexity of fabricating the solar cell 20.

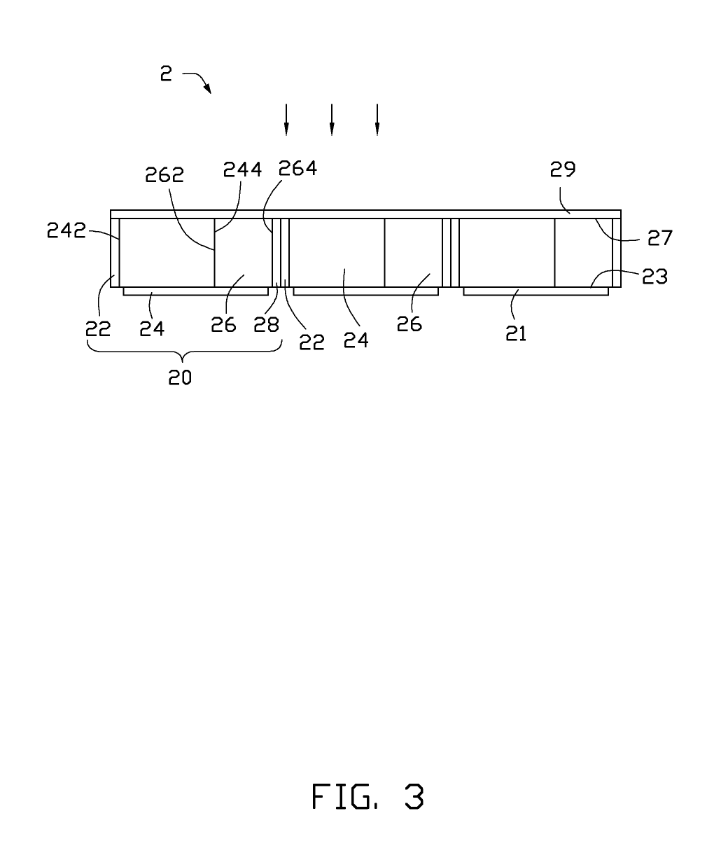

Referring to FIG. 3, one embodiment of a solar cell system 2 includes a plurality of the aforementioned solar cells 20 connected in series. The plurality of solar cells 20 are arranged side by side and contacting directly each other. The second electrode layer 28 of each solar cell 20 contacts the first electrode layer 22 of the adjacent solar cell 20. The first surfaces 27 of the plurality of solar cells 20 are coplanar and cooperatively form the photoreceptive surface of the solar cell system 2 to directly receive incident light. Furthermore, a common antireflection layer 29 is disposed on the first surfaces 27 of the solar cell system 2, thereby decreasing light reflecting from the photoreceptive surface and increasing light absorption of the P-N junction.

The second electrode layer 28 of each solar cell 20 and the first electrode layer 22 of the adjacent solar cell 20 can be bonded with each other or adhered to each other by a conductive adhesive. The material of the second electrode layer 28 of each solar cell 20 and the first electrode layer 22 of the adjacent solar cell 20 can be the same or different. If the material of the second electrode layer 28 of each solar cell 20 and the first electrode layer 22 of the adjacent solar cell 20 are the same, the adjacent two solar cells 20 can share a common electrode layer. In one embodiment, the plurality of solar cells 20 can be pressed together to form an integral structure.

In the solar cell system 2, a total thickness of the first electrode layer 22 of each solar cell 20 and the second electrode layer 28 of the adjacent solar cell 20 can be in a range from about 100 nm to about 400 nm. In one embodiment, the total thickness of the first electrode layer 22 of each solar cell 20 and the second electrode layer 28 of the adjacent solar cell 20 along a direction from the first side surface 242 to the second side surface 244 is about 300 nm. Thus, the solar cell system 2 can has a relatively greater photoreceptive surface.

The number of the solar cells 20 in the solar cell system 2 is not limited and can be set according to an output voltage of the solar cell system 2. In one embodiment, the solar cell system 2 includes one hundred solar cells 20. An operating voltage of the solar cell system 2 is an integral multiple of the operating voltage of one solar cell 20.

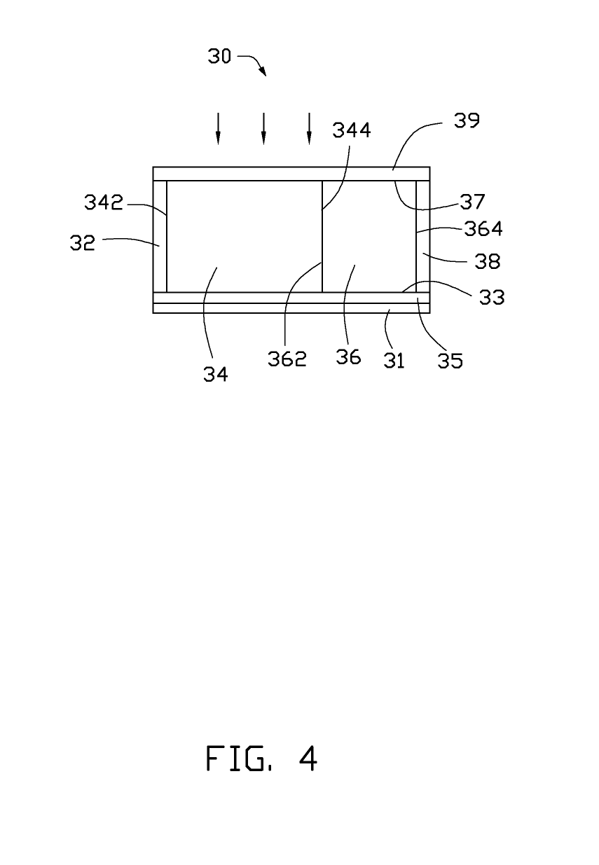

Referring to FIG. 4, a second embodiment of a solar cell 30 includes a first electrode layer 32, a P-type silicon layer 34, an N-type silicon layer 36, a second electrode layer 38, and a reflector 31.

The first electrode layer 32, the P-type silicon layer 34, the N-type silicon layer 36, and the second electrode layer 38 can be arranged in series along a first direction, side by side, in that order, cooperatively forming an integrated structure. The integrated structure includes a first surface 37 and a second surface 33 opposite to the first surface 37. The first surface 37 is parallel with the first direction and used as a photoreceptive surface to receive an incident light. In particular, the P-type silicon layer 34 has a first side surface 342 and a second side surface 344 opposite to the first side surface 342. The N-type silicon layer 36 has a third side surface 362 and a fourth side surface 364 opposite to the third side surface 362. The first electrode layer 32 is electrically connected with and contacting the first side surface 342 of the P-type silicon layer 34. The second electrode layer 38 is electrically connected with and contacting the fourth side surface 364 of the N-type silicon layer 36. The second side surface 344 of the P-type silicon layer 34 and the third side surface 362 of the N-type silicon layer 36 are electrically connected with and contacting each other to form a P-N junction. The reflector 31 is located on the second surface 33 and insulated from the first electrode layer 32 and the second electrode layer 38. The solar cell 30 is similar to the solar cell 20 provided above, the difference is that the reflector 31 is spaced from the second surface 33.

In one embodiment, the reflector 31 is spaced from the second surface 33 by a transparent insulating layer 35. The transparent insulating layer 35 is located on the covers the entire second surface 33. The reflector 31 is continuous reflection layer located on and covers the entire transparent insulating layer 35. The transparent insulating layer 35 is made of material with a certain chemical stability, such as diamond-like carbon, silicon, silicon carbide, silicon dioxide, silicon nitride, aluminum oxide or boron nitride. The thickness of the transparent insulating layer 35 can be in a range from about 10 nm to about 100 μm. In one embodiment, the thickness of the transparent insulating layer 35 can be in a range from about 10 nm to about 50 nm in order to reduce the light absorption. The transparent insulating layer 35 can be coated on the second surface 33 by physical vapor deposition (PVD) or chemical vapor deposition (CVD). The reflector 31 can be formed on the transparent insulating layer 35 by vacuum evaporation or magnetron sputtering.

In one embodiment, the reflector 31 is free standing, suspended and spaced from the second surface 33. The distance between the reflector 31 and the second surface 33 can be in a range from about 1 millimeters (mm) to about 5 centimeters (cm). If the reflector 31 is not free standing, a plate (not shown) can be used to support the reflector 31. The plate can be a glass plate, ceramic plate or silicon plate. The reflector 31 can be formed on the plate by vacuum evaporation or magnetron sputtering.

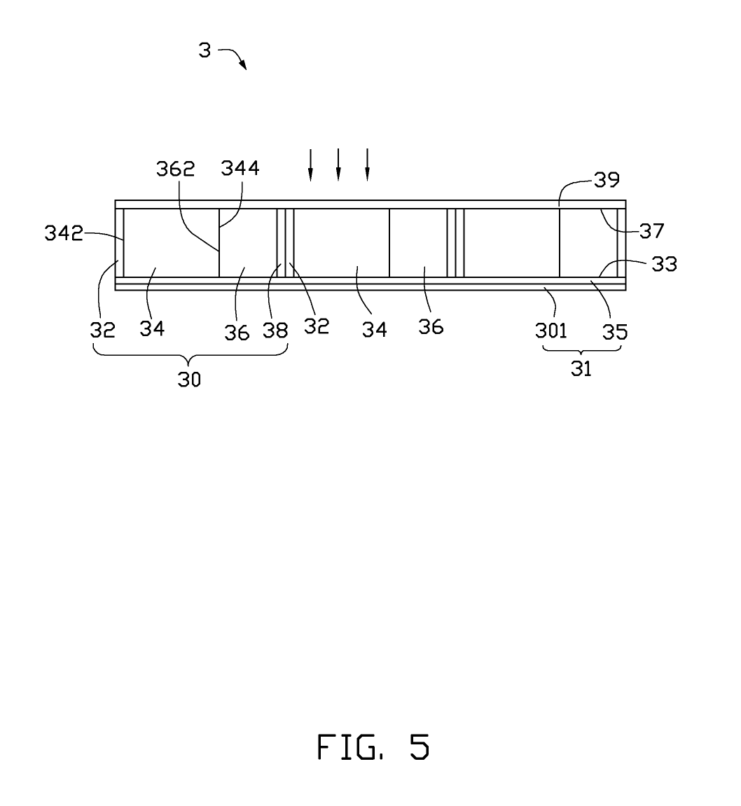

Referring to FIG. 5, one embodiment of a solar cell system 3 includes a plurality of the aforementioned solar cells 30 connected in series. The plurality of solar cells 30 are arranged side by side and contacting directly each other. The second electrode layer 38 of each solar cell 30 contacts the first electrode layer 32 of the adjacent solar cell 30. The surfaces 37 of the plurality of solar cells 30 are coplanar and cooperatively form the photoreceptive surface of the solar cell system 3 to directly receive incident light. Furthermore, a common antireflection layer 39 is disposed on the first surfaces 37 of the solar cell system 3, thereby decreasing light reflecting from the photoreceptive surface and increasing light absorption of the P-N junction. The solar cell system 3 is similar to the solar cell system 2 provided above, the difference is that the reflector 31 is spaced from the second surface 33.

In one embodiment, a common reflector 31 is spaced from the second surface 33 by a common transparent insulating layer 35. The transparent insulating layer 35 is located on the covers the entire second surfaces 33. The reflector 31 is continuous reflection layer located on and covers the entire transparent insulating layer 35. In one embodiment, a common reflector 31 is located on a plate, suspended and spaced from the second surface 33.

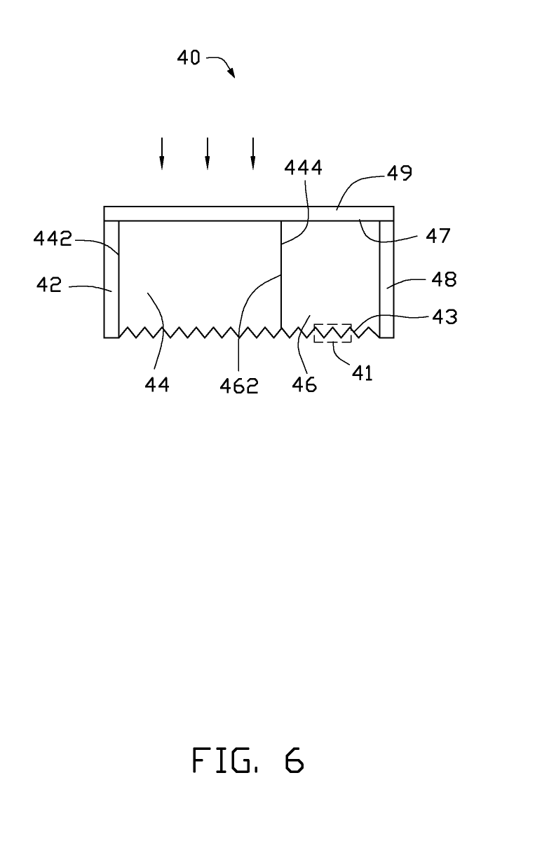

Referring to FIG. 6, a third embodiment of a solar cell 40 includes a first electrode layer 42, a P-type silicon layer 44, an N-type silicon layer 46, a second electrode layer 48 and a reflector 41.

The first electrode layer 42, the P-type silicon layer 44, the N-type silicon layer 46, and the second electrode layer 48 can be arranged in series along a first direction, side by side, in that order, cooperatively forming an integrated structure. The integrated structure includes a first surface 47 and a second surface 43 opposite to the first surface 47. The first surface 47 is parallel with the first direction and used as a photoreceptive surface to receive an incident light. In particular, the P-type silicon layer 44 has a first side surface 442 and a second side surface 444 opposite to the first side surface 442. The N-type silicon layer 46 has a third side surface 462 and a fourth side surface 464 opposite to the third side surface 462. The first electrode layer 42 is electrically connected with and contacting the first side surface 442 of the P-type silicon layer 44. The second electrode layer 48 is electrically connected with and contacting the fourth side surface 464 of the N-type silicon layer 46. The second side surface 444 of the P-type silicon layer 44 and the third side surface 462 of the N-type silicon layer 46 are electrically connected with and contacting each other to form a P-N junction. The reflector 41 is located on the second surface 43. The solar cell 40 is similar to the solar cell 20 provided above, the difference is that the reflector 41 is a plurality of micro-structures.

Each of the plurality of micro-structures can be a concave groove in the P-type silicon layer 44 and the N-type silicon layer 46 or a protrusion protruding from the P-type silicon layer 44 and the N-type silicon layer 46. Each of the plurality of micro-structures can be V-shaped, cylindrical, hemispherical, or pyramid-shaped. The micro-structures can be formed by etching the second surface 43. Furthermore, the micro-structures can be coated with a reflecting material such as aluminum, gold, copper or silver by vacuum evaporation or magnetron sputtering.

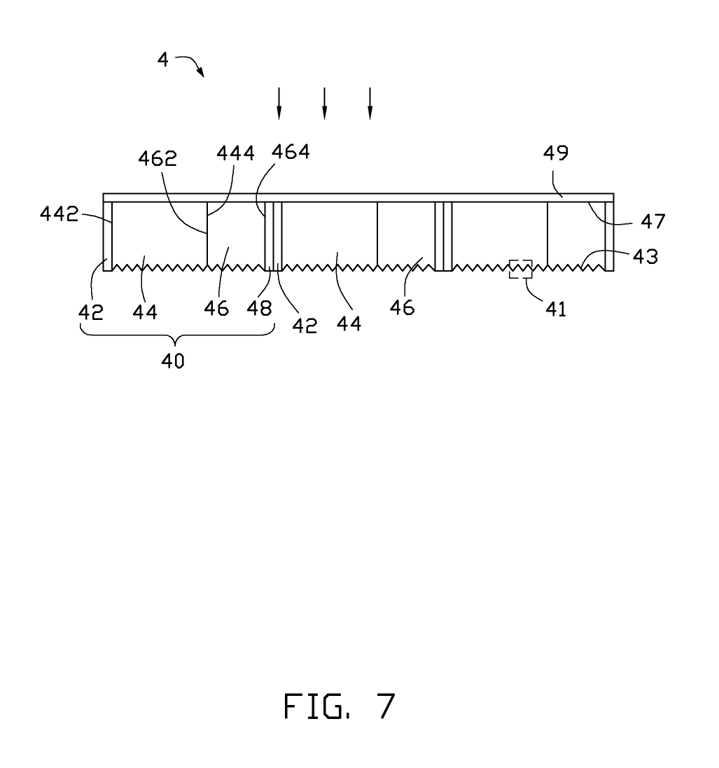

Referring to FIG. 7, one embodiment of a solar cell system 4 includes a plurality of the aforementioned solar cells 40 connected in series. The plurality of solar cells 40 are arranged side by side and directly contacting each other. The second electrode layer 48 of each solar cell 40 contacts the first electrode layer 42 of the adjacent solar cell 40. The surfaces 47 of the plurality of solar cells 40 are coplanar and cooperatively form the photoreceptive surface of the solar cell system 4 to directly receive incident light. Furthermore, a common antireflection layer 49 is disposed on the first surfaces 47 of the solar cell system 4, thereby decreasing light reflecting from the photoreceptive surface and increasing light absorption of the P-N junction. The solar cell system 4 is similar to the solar cell system 2 provided above, the difference is that the reflector 41 is a plurality of micro-structures.

In one embodiment, each of the plurality of micro-structures can be a concave groove in the P-type silicon layer 44 and the N-type silicon layer 46. In one embodiment, each of the plurality of micro-structures can be a protrusion protruding from the P-type silicon layer 44 and the N-type silicon layer 46.

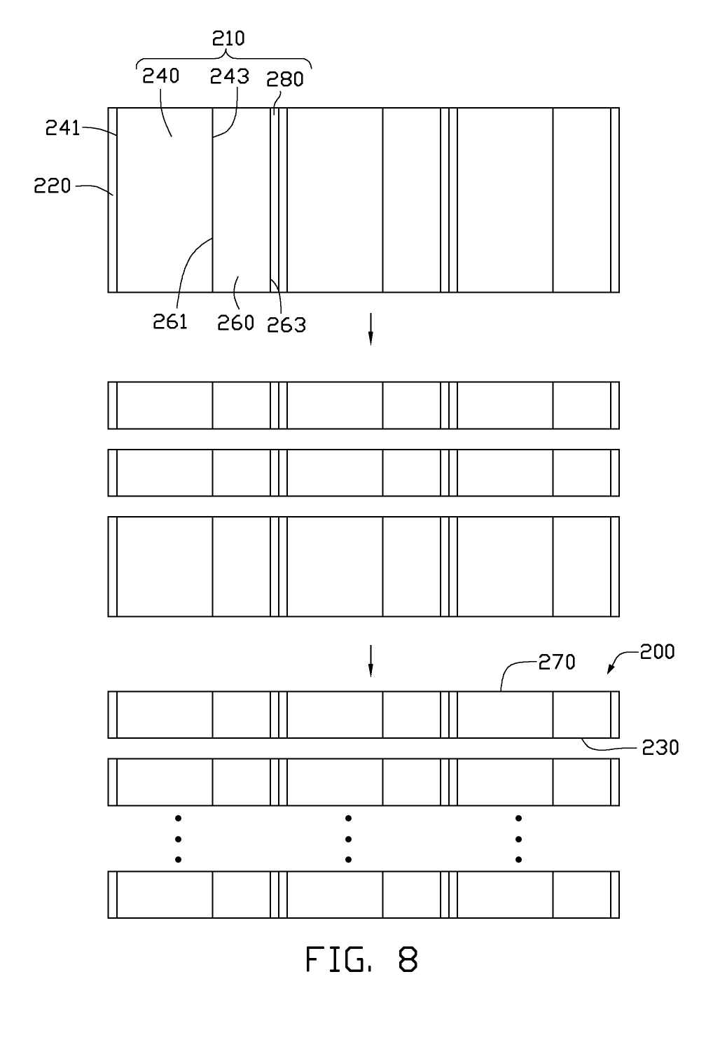

Referring to FIG. 8, one embodiment of a method for making a solar cell system 200 includes the following steps:

S1, providing a plurality of cell performing elements 210, wherein each of the cell performing elements 210 includes a first electrode substrate 220, a P-type silicon substrate 240, an N-type silicon substrate 260, and a second electrode substrate 280 arranged in series along a first direction and in contact with each other;

S2, laminating the plurality of cell performing elements 210 in series along the first direction, wherein the first electrode substrate 220 of each cell performing element 210 is in contact with the second electrode substrate 240 of one adjacent cell performing element 210;

S3, cutting the plurality of cell performing elements 210 along the first direction, thereby forming at least one solar cell system 200 having a integrated structure having a first surface 270 parallel to the first direction and a second surface 230 opposite to the first surface 270; and

S4, forming a reflector (not shown) on the second surface 230.

In step S1, the P-type silicon substrate 240 has a first surface 241 and a second surface 243 opposite to the first surface 241. The N-type silicon substrate 260 has a first surface 261 and a second surface 263 opposite to the first surface 261. The first electrode substrate 220 is disposed on the first surface 241 of the P-type silicon substrate 240. The second electrode substrate 280 is disposed on the second surface 263 of the N-type silicon substrate 260. The second surface 243 of the P-type silicon substrate 240 contacts the first surface 261 of the N-type silicon substrate 260, thereby forming a P-N junction. The P-type silicon substrate 240 is a P-type silicon sheet. A material of the P-type silicon sheet can be monocrystalline silicon, polycrystalline silicon, or other P-type semiconducting material. In one embodiment, the P-type silicon substrate 240 is a P-type monocrystalline silicon sheet. A thickness of the P-type monocrystalline silicon sheet can be in a range from about 200 μm to about 300 μm. A shape and area of the P-type silicon substrate 240 are not limited and can be set as needed. The N-type silicon substrate 260 can be formed by injecting surplus N-type doping elements (e.g. phosphorus or arsenic) into a silicon sheet. A thickness of the N-type silicon substrate 260 can be in a range from about 10 nm to about 1 μm.

A material of the first electrode substrate 220 and a material of the second electrode substrate 280 can be the same or different. In one embodiment, the first electrode substrate 220 and the second electrode substrate 280 can be composed of a metal layer having a continuous integrated structure. The metal layer can be made of aluminum, copper, or silver. The first electrode substrate 220 and the second electrode substrate 280 can be respectively adhered on the P-type silicon substrate 240 and the N-type silicon substrate 260 by a conductive adhesive, or respectively formed on the P-type silicon substrate 240 and the N-type silicon substrate 260 by a process of vacuum evaporating or magnetron sputtering.

In step S2, the plurality of cell performing elements 210 can be adhered to each other by a conductive adhesive. In addition, if a material of the first electrode substrate 220 of each cell performing element 210 is the same as a material of the second electrode substrate 280 of the adjacent cell performing element 210, the plurality of cell performing elements 210 can be pressed together by a pressing machine, thereby bonding together the electrode substrates of the two adjacent cell performing elements 210. A force applied on the plurality of cell performing elements 210 by the pressing machine is not limited and can be applied to bond the first electrode substrate 220 and the second electrode substrate 280 in the adjacent cell performing elements 210 into an integrative structure.

In S3, the cutting method is not limited. The plurality of cell performing elements 210 in contact with each other are cut along the first direction passing through the first surface 241 and the second surface 243 of the P-type silicon substrate 240, and the first surface 261 and the second surface 263 of the N-type silicon substrate 260, thereby forming at least one solar cell system 200 having a integrated structure having a first surface 270 and a second surface 230 opposite to the first surface 270. The first surface 270 of the integrated structure is parallel to the cutting direction. In one embodiment, the cutting direction is perpendicular to the first surface 241 and the second surface 243 of the P-type silicon substrate 240, and the first surface 261 and the second surface 263 of the N-type silicon substrate 260.

In S4, the reflector can be formed by different methods. In one embodiment, the reflector is a continuous reflection layer and can be deposited on the second surface 230 by vacuum evaporation or magnetron sputtering. The first electrode substrates 220 and the second electrode substrates 280 are shielded before depositing the reflection layer so that the first electrode substrates 220 and the second electrode substrates 280 are insulated from each other. In one embodiment, a transparent insulating layer is formed to cover the entire second surface 230 and the reflector is a continuous reflection layer and can be deposited on the transparent insulating layer by vacuum evaporation or magnetron sputtering. In one embodiment, the reflector is a plurality of micro-structures and can be formed by etching the second surface 230. Furthermore, the micro-structures can be coated with a reflecting material such as aluminum, gold, copper or silver by vacuum evaporation or magnetron sputtering.

Furthermore, after step S4, an antireflection layer (not shown) can be formed on the first surface 270 by a process of vacuum evaporating or magnetron sputtering.

Depending on the embodiment, certain steps of methods described may be removed, others may be added, and the sequence of steps may be altered. It is also to be understood, that the description and the claims drawn to a method may include some indication in reference to certain steps. However, the indication used is only to be viewed for identification purposes and not as a suggestion as to an order for the steps.

Finally, it is to be understood that the above-described embodiments are intended to illustrate rather than limit the present disclosure. Variations may be made to the embodiments without departing from the spirit of the present disclosure as claimed. Elements associated with any of the above embodiments are envisioned to be associated with any other embodiments. The above-described embodiments illustrate the scope of the present disclosure but do not restrict the scope of the present disclosure.

What is claimed is:

1. A solar cell, comprising:
a first electrode layer, a P-type silicon layer, an N-type silicon layer, a second electrode layer, wherein the first electrode layer, the P-type silicon layer, the N-type silicon layer, and the second electrode layer are arranged in series side by side along a first direction and in contact with each other, thereby cooperatively forming an integrated structure and a P-N junction is formed near an interface between the P-type silicon layer and the N-type silicon layer, the integrated structure having a first surface substantially parallel to the first direction and a second surface opposite to the first surface, the first surface is used as a photoreceptive surface to directly receive incident light; and
a reflector located on the second surface of the integrated structure.

2. The solar cell as claimed in claim 1, wherein the P-type silicon layer has a first surface and a second surface opposite to the first surface, the N-type silicon layer has a first surface and a second surface opposite to the first surface, the first electrode layer is electrically contacted with the first surface of the P-type silicon layer, the second electrode layer is electrically contacted with the second surface of the N-type silicon layer, the P-type silicon layer has a first side surface connected with the first surface and the second surface of the P-type silicon layer, the N-type silicon layer has a second side surface connected with the first surface and the second surface the N-type silicon layer, and the first side surface and the second side surface cooperatively form the photoreceptive surface.

3. The solar cell as claimed in claim 2, wherein the first electrode layer has a continuous planar shaped structure coated on the entire first surface of the P-type silicon layer, the second electrode layer has a continuous planar shaped structure coated on the entire second surface of the N-type silicon layer.

4. The solar cell as claimed in claim 3, wherein the first electrode layer and the second electrode layer are opaque metal layer.

5. The solar cell as claimed in claim 2, wherein the incident light irradiates the photoreceptive surface along a direction substantially perpendicular to the first surface of the integrated structure.

6. The solar cell as claimed in claim 1, wherein an antireflection layer having a thickness of about 150 nm is coated on the first surface of the integrated structure.

7. The solar cell as claimed in claim 6, wherein a material of the antireflection layer is silicon nitride or silicon dioxide.

8. The solar cell as claimed in claim 1, wherein the P-N junction is exposed out from the photoreceptive surface.

9. The solar cell as claimed in claim 1, wherein a thickness of the solar cell between the first surface and the second surface of the solar cell is in a range from about 50 μm to about 300 μm.

10. The solar cell as claimed in claim 1, wherein the reflector is a continuous reflection layer directly in contact with the second surface and spaced from the first electrode layer and the second electrode layer.

11. The solar cell as claimed in claim 10, wherein the reflector is made of metal selected from group consisting of aluminum, gold, copper and silver.

12. The solar cell as claimed in claim 1, wherein a transparent insulating layer is located between the reflector and the second surface.

13. The solar cell as claimed in claim 1, wherein the reflector is free standing and spaced from the second surface.

14. The solar cell as claimed in claim 1, wherein the reflector is a plurality of micro-structures.

15. The solar cell as claimed in claim 14, wherein each of the plurality of micro-structures is a groove or a protrusion.

16. The solar cell as claimed in claim 14, wherein each of the plurality of micro-structures is V-shaped, cylindrical, hemispherical, or pyramid-shaped.

17. A solar cell system, comprising:
a plurality of solar cells connected in series, each of the plurality of solar cells comprising:
a first electrode layer, a P-type silicon layer, an N-type silicon layer, a second electrode layer, wherein the first electrode layer, the P-type silicon layer, the N-type silicon layer, and the second electrode layer are arranged in series side by side along a first direction and in contact with each other, thereby cooperatively forming an integrated structure and a P-N junction is formed near an interface between the P-type silicon layer and the N-type silicon layer, the integrated structure having a first surface substantially parallel to the first direction and a second surface opposite to the first surface, the first surface is used as a photoreceptive surface to directly receive incident light; and
a reflector located on the second surface of the integrated structure.

18. The solar cell system as claimed in claim 17, wherein the first electrode layer of each of the plurality of solar cells is in contact with the second electrode layer of one adjacent solar cell of the plurality of solar cells.

19. A solar cell system, comprising:
a plurality of solar cells connected in series, each of the plurality of solar cells comprising: a first electrode layer, a P-type silicon layer, an N-type silicon layer, a second electrode layer, wherein the first electrode layer, the P-type silicon layer, the N-type silicon layer, and the second electrode layer are arranged in series side by side along a first direction and in contact with each other, thereby cooperatively forming an integrated structure and a P-N junction is formed near an interface between the P-type silicon layer and the N-type silicon layer, the integrated structure having a first surface substantially parallel to the first direction and a second surface opposite to the first surface, the first surface is used as a photoreceptive surface to directly receive incident light;
a common transparent insulating layer located on and covering all the second surfaces of the integrated structures; and
a common reflector located on the common transparent insulating layer.

20. The solar cell system as claimed in claim 19, wherein the first electrode layer of each of the plurality of solar cells is in contact with the second electrode layer of one adjacent solar cell of the plurality of solar cells.
